(19) United States
(12) Patent Application Publication
(10) Pub. No.: US 2017/0198143 A1
(43) Pub. Date: Jul. 13, 2017

(54) FLUORESCENT DYE COMPOUND HAVING BENZOTRIAZOLE STRUCTURE, POLYMER FLUORESCENT DYE COMPOUND AND WAVELENGTH-CONVERTING ENCAPSULANT COMPOSITION USING SAME

(71) Applicant: NITTO DENKO CORPORATION, Osaka (JP)

(72) Inventors: Sadahiro NAKANISHI, Osaka (JP); Shoichi KAWAMITSU, Osaka (JP); Miyuki KUROGI, Osaka (JP); Hisanari ONOUCHI, Osaka (JP)

(21) Appl. No.: 15/327,775

(22) PCT Filed: Jul. 16, 2015
(86) PCT No.: PCT/JP2015/070401

§ 371 Date: Jan. 20, 2017

(30) Foreign Application Priority Data
Jul. 24, 2014 (JP) 2014-150581

(51) Int. Cl. C09B 69/10; C09K 11/06; C09K 11/02; H01L 31/055; C08F 20/68; C08G 61/10; C08F 10/14; H01L 31/048; C09B 57/00; C08L 23/08

(52) U.S. Cl. CPC C09B 69/10; C09B 57/00; C09K 11/06; C09K 11/02; C08L 23/0853; C08F 20/68; C08G 61/10; C08F 10/14; H01L 31/0481; H01L 31/055; C09K 2211/1466; C09K 2211/1425; C08G 2261/91; C08G 2261/522; C08G 2261/312; C08G 2261/228; C08G 2261/1424; C08G 2261/149; C08G 2261/148; C08L 2203/204

(57) ABSTRACT

The present invention relates to fluorescent, benzotriazole-containing dye compounds, which possess high processability, desirable optical characteristics and good photostability, while suppressing the formation of a precipitate, and to dye polymers comprising the same. The present invention further relates to a wavelength-converting encapsulant composition comprising said dye polymer and to a photovoltaic module, which comprises a layer comprising said wavelength-converting encapsulant. The polymer fluorescent benzotriazole-containing dye compound is represented by general formula (I):

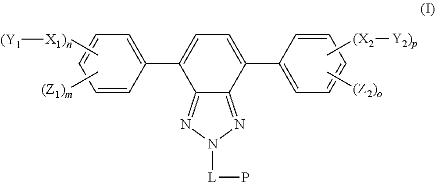

where the variables are defined in the specification.

### TECHNICAL FIELD

The present invention relates to a fluorescent dye polymeric compound which has a benzotriazole structure to have a favorable absorption wavelength and an excellent light stability when used in, e.g., a solar cell encapsulant or a fluorescent film forming material; a fluorescent dye compound which is a precursor of the polymeric compound; and a wavelength-converting encapsulant composition, a wavelength-converting encapsulant layer (such as a wavelength-converting film or a wavelength-converting sheet), and a solar cell module each using the polymeric compound. The wavelength-converting encapsulant layer has a potential of attaining a remarkable enhancement of the sunlight collecting efficiency of a photoelectromotive device or a solar cell device.

### BACKGROUND ART

The use of solar energy supplies a promising energy alternate for conventional fossil fuels. In recent years, therefore, a great attention has been paid to the development of devices capable of converting solar energy to electricity, for example, the development of a photoelectromotive device (also known as a solar cell) and others. Mature photoelectromotive devices of some different types have been developed. Examples thereof include silicon devices, III-V and II-VI PN junction devices, copper-indium-gallium-selenium (CIGS) thin film devices, organic sensitizer devices, organic thin film devices, and cadmium-sulfide/cadmium-telluride (CdS/CdTe) thin film devices. Details of these devices can be found out in documents and others (see, for example, Non-Patent Document 1). However, about the photoelectric conversion efficiency of many of these devices, there has still been a room for improvement. For many researches, the development of a technique for improving this efficiency is a theme which is being tackled.

In order to improve the conversion efficiency, investigations have been made about solar cells having such a wavelength-converting function that wavelengths not contributing to photoelectric conversion (for example, ultraviolet wavelengths), out of wavelengths of rays radiated into the cells, are converted to wavelengths contributing to photoelectric conversion (see, for example, Patent Document 2). According to the investigations, a suggestion is made about a method of mixing a fluorophore powder with a resin material to form an emission panel.

Wavelength-converting inorganic media to be used in photoelectromotive devices and solar cells have been so far disclosed. However, reports have hardly been made about researches on the use of a photoluminescent organic medium in a photoelectromotive device for improving the efficiency of the device. In contrast to inorganic media, organic material is typically more inexpensive, and is easier to use. From this matter, attention is paid to the use of organic media in the point that the selection of organic material becomes a better economical selection.

It has also made evident that the use of the above-mentioned fluorophore powder causes inconveniences, for example, the precipitation of the added fluorophore with time. In a case where the powder is used, particularly, for solar cells, improvements of such a stability over time, and storage stability for a long term are particularly important themes since it is conceived that the solar cells are used outdoors over a long term of 20 years or longer.

### PRIOR ART DOCUMENTS

### Patent Documents

PATENT DOCUMENT 1: US-A-2009/0151785

PATENT DOCUMENT 2: JP-A-H07-142752

### SUMMARY OF THE INVENTION

### Problems to be Solved by the Invention

In light of such a situation, an object of the present invention is to provide a fluorescent dye compound which is a benzotriazole derivative as a novel compound that has a high workability, desired optical properties and a good light stability, and that restrains the generation of any precipitation; a fluorescent dye polymeric compound having a benzotriazole structure; and a wavelength-converting encapsulant composition using this polymeric compounds.

Another object of the present invention is to provide a wavelength-converting encapsulant layer which is formed using the wavelength-converting encapsulant composition, thereby having desired optical properties and a good light stability and restraining the generation of any precipitation; and a photoelectromotive module having this layer.

### Means for Solving the Problems

In order to solve the above-mentioned problems, the inventors have made eager investigations to succeed in creating a novel organic compound and a polymeric compound each having a novel benzotriazole structure described below, and have found out that the above-mentioned objects can be attained through the organic compound and the polymeric compound. Thus, the present invention has been accomplished.

The polymer fluorescent dye compound of the present invention is represented by the following general formula (I):

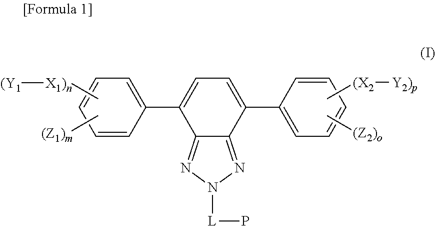

wherein X₁ (s) and X₂ (s) each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;

Y₁(s) and Y₂(s) each independently represent an optionally-substituted alkyl group having 1 to 18 carbon atoms (provided that one or two out of any nonadjacent two of the carbon atoms in the alkyl group may (each) be substituted with an oxygen atom);

P represents a polymeric structural moiety;

L represents a linker structural moiety through which a benzotriazole ring of the compound and the polymeric structural moiety are bonded to each other by a covalent bond;

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the substituents concerned may be the same as or different from each other.

The polymer fluorescent dye compound of the present invention has the structure represented by the general formula (I). Thus, the compound can be an excellent compound having a high workability, desired optical properties (such as a high quantum yield) and a good light stability (chemical and physical stability). The polymeric dye compound which is, particularly, dispersed in a matrix resin can easily give a stable and uniform encapsulant composition (and layer) without being precipitated even in a long-term storage test. About the expression of the effects and advantages, it is presumed at present that a mechanism described below contributes mainly to the expression. However, it is not specified that the expression is indispensably via the mechanism. It is presumed about the polymer fluorescent dye compound (benzotriazole-structure-containing polymer) that: its benzotriazole moiety which effects as a fluorescent dye is chemically linked to a structural moiety of the polymer to be restrained from being shifted inside the matrix resin; and consequently this compound can be restrained from undergoing, for example, crystallization followed by being precipitated or being discharged to the outside of the layer.

When a fluorescence-emitting chemical structure moiety of a compound molecule is linked to a different aromatic moiety of the or another molecule, the compound may be unfavorably changed in absorbing/light-emitting properties, and further the aromatic moiety formed by the linking may also be lowered in light stability. Thus, it is feared that the compound is deteriorated, particularly, in absorbing/light-emitting properties and others when this compound is used outdoors for, e.g., solar cells. In contrast, about the polymer fluorescent dye compound of the present invention, its chromophore having the specific benzotriazole structure is linked to its base polymeric structure to a nitrogen atom at the 2-position of the benzotriazole ring through a noncovalent bond. In this way, the absorbing/light-emitting properties of this chromophore are substantially kept to make it easy to predict or adjust the absorbing/light-emitting properties of the polymer fluorescent dye compound on the basis of the introduction of the chromophore into the polymeric body. Moreover, about the polymer fluorescent dye compound of the present invention, for example, a bonding moiety of the benzotriazole structure is, for example, bonded to not only a monomer moiety of the polymer fluorescent dye compound that expresses a main function of the polymeric compound but also a different monomer moiety, thereby making it possible to control secondary properties of the polymer fluorescent dye compound, such as the glass transition temperature (Tg) and solubility thereof. This matter is advantageous for making it easier to disperse or dissolve this dye compound evenly in the system concerned in the step of working the compound or the encapsulant composition, for example, the step of heating and kneading the same. In general, a dye compound having a heterocyclic structure may be poor in solubility because of the planarity or crystallinity thereof. However, the polymer fluorescent dye compound of the present invention is a polymeric body to be excellent in workability. When a novel compound having a low molecular weight is put into the market, it is usually necessary to make individual tests, a registration, and others on the basis of the Chemical Substance Control Law of Japan; however, the polymer fluorescent dye compound of the present invention is a polymeric body to be handled as a compound to be restrictedly taken into any living body. Thus, the tests and the others can be made with less procedural and horal burden.

In the polymer fluorescent dye compound of the present invention, it is preferred that the symbol L is combined neither with the benzotriazole ring nor with the polymeric structural moiety for the formation of any conjugated bond. When the compound has this structure, the following is restrained: the linker structural moiety changes the non-localization of the conjugated system or electrons of the compound to affect the absorbing/light-emitting properties of the chromophore. As a result, this compound substantially keeps the absorbing/light-emitting properties of the chromophore before the incorporation of the chromophore into the polymeric structural moiety, or before the polymerization into the polymeric dye compound, thereby making it easier to predict or adjust the absorbing/light-emitting properties of the polymeric compound on the basis of the introduction of the chromophore into the polymeric body.

The polymer fluorescent dye compound of the present invention is preferably represented by the following general formula (II):

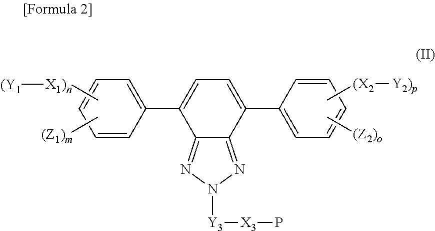

wherein X₁(s), X₂(s) and X₃ each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;

Y₁(s), Y₂(s) and Y₃ each independently represent an optionally-substituted alkyl group having 1 to 18 carbon atoms (provided that one or two out of any nonadjacent two of the carbon atoms in the alkyl group may (each) be substituted with an oxygen atom);

P represents a polymeric structural moiety;

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the substituents concerned may be the same as or different from each other.

In the polymer fluorescent dye compound of the present invention, it is preferred that the symbol P is polyethylene terephthalate, poly(meth)acrylate, polyvinyl acetate, polyethylene tetrafluoroethylene, polyimide, amorphous polycarbonate, siloxane sol-gel, polyurethane, polystyrene, polyethersulfone, polyarylate, epoxy resin, polyethylene, polypropylene, poly(ethylene-vinyl acetate) or silicone resin. In the use of the compound for a wavelength-converting encapsulant composition, it is preferred to use, as the above-mentioned resin, an optically transparent resin. By using, particularly, a resin identical with the matrix resin of the wavelength-converting encapsulant composition or a resin high in affinity with the matrix resin, this compound becomes a compound better for being evenly dispersed in a layer of the encapsulant composition or being restrained from being precipitated.

It is also preferred that the polymer fluorescent dye compound of the present invention has a maximum absorption wavelength in a wavelength range from 300 to 410 nm. When the compound has the maximum absorption wavelength in this wavelength range, the compound makes it possible to convert more effectively incident rays having wavelengths which are not easily used (or not usable) for photoelectric conversion by a solar cell into a wavelength range which can be photoelectrically converted by the solar cell or the like. In the invention, the maximum absorption wavelength denotes a wavelength at which the absorbance of the light absorbed by this compound is a maximum value, and is measurable as a wavelength at which the compound shows a maximum absorption peak in an ultraviolet absorption spectrum thereof.

It is also preferred that the polymer fluorescent dye compound of the present invention has a maximum fluorescence emission wavelength in a wavelength range from 410 to 560 nm. When the compound has the maximum fluorescence emission wavelength in this wavelength range, the compound makes it possible to convert more effectively incident rays having wavelengths which are not easily used (or not usable) for photoelectric conversion by a solar cell into a wavelength range which can be photoelectrically converted by the solar cell. In the invention, the maximum fluorescence emission wavelength denotes a wavelength of a ray showing a maximum emission intensity, out of light rays emitted from the compound, and is measurable as a wavelength at which the compound shows a maximum emission peak in a fluorescence emission spectrum thereof.

The wavelength-converting encapsulant composition of the present invention includes the above-defined polymer fluorescent dye compound. The wavelength-converting encapsulant composition may be a composition including an optically transparent resin matrix and the polymer fluorescent dye compound. When the composition includes the polymer fluorescent dye compound, rays having shorter wavelengths than wavelengths which a solar cell absorbs can be efficiently red-shifted into the range of wavelengths which the solar cell can use for photovoltaics. Consequently, a broader spectrum of solar energy can be converted into electricity. Moreover, the polymer fluorescent dye compound has a large fluorescent quantum efficiency and a good workability, so that the compound can give a wavelength-converting encapsulant composition supplying an excellent photoelectric conversion effect, advantageously for the production process of the composition and costs. Furthermore, the wavelength-converting encapsulant composition of the invention receives, as an input, at least one photon having a first wavelength to give, as an output, at least one photon having a second wavelength longer (larger) than the first wavelength. In this process, the wavelength-converting encapsulant composition expresses an original function of the composition. Furthermore, even when the wavelength-converting encapsulant composition is subjected to a storage test over a long period, the polymer fluorescent dye compound dispersed in the matrix resin is not precipitated therefrom. Thus, the present invention can easily give a stable and uniform encapsulant composition (and layer). The wavelength-converting encapsulant composition is particularly suitable for solar cells.

It is preferred that the wavelength-converting encapsulant composition includes the polymer fluorescent dye compound in a proportion of 0.05 to 100% by weight.

The wavelength-converting encapsulant composition of the present invention may be rendered a composition including an optically transparent resin matrix and the polymer fluorescent dye compound recited in any one of claims 1 to 6.

It is preferred in the wavelength-converting encapsulant composition of the present invention that the matrix resin includes, as a main component thereof, poly(ethylene-vinyl acetate). When the matrix resin includes, as the main component thereof, poly(ethylene-vinyl acetate), this layer can be, with a higher certainty, rendered a wavelength-converting encapsulant layer excellent in light transmittance and endurance.

When the matrix resin is rendered a mixture of plural resins, the wording “AA includes, as a main component thereof, a resin BB” denotes a case where the resin BB is included at a ratio by weight of 50% or more of the AA. The ratio by weight is more preferably 70% or more by weight, even more preferably 90% or more by weight.

Furthermore, the wavelength-converting encapsulant layer of the present invention is formed, using the above-mentioned wavelength-converting encapsulant composition. By the formation using the composition, the composition is turned to a wavelength-converting encapsulant layer which has desired optical properties (such as a high quantum yield) and a good light stability (chemical and physical stability), and which restrains the generation of any precipitation. In more detail, the polymer fluorescent dye compound has a large fluorescent quantum efficiency and a good workability; thus, the compound can give a wavelength-converting encapsulant layer supplying an excellent photoelectric conversion effect, advantageously for a production process of the layer and costs. Moreover, the wavelength-converting encapsulant layer of the present invention receives, as an input, at least one photon having a first wavelength to give, as an output, at least one photon having a second wavelength longer (larger) than the first wavelength. In this process, the wavelength-converting encapsulant layer expresses an original function of this layer. Furthermore, even when the wavelength-converting encapsulant layer is subjected to a storage test over a long period, the polymer fluorescent dye compound dispersed in the matrix resin is not precipitated therefrom. Thus, the present invention can easily give a stable and uniform encapsulant composition layer. The wavelength-converting encapsulant layer is particularly suitable for solar cells.

The solar cell module of the present invention includes a wavelength-converting encapsulant layer formed using the above-defined wavelength-converting encapsulant composition. Since the solar cell module has the wavelength-converting encapsulant layer, the solar cell module is a solar cell module having desired optical properties (such as a high quantum yield) and a good light stability (chemical and physical property). Furthermore, the solar cell module does not cause the polymer fluorescent dye compound to precipitate in a storage test over a long period since the solar cell module has the wavelength-converting encapsulant layer. Thus, the polymer fluorescent dye compound can be restrained from being shifted to a encapsulant layer for the rear surface of the module, or to some other member. The solar cell module is a stable and uniform solar cell module.

It is preferred that the solar cell module of the present invention is configured to cause a light ray radiated into the module to pass through the wavelength-converting encapsulant layer before the light ray reaches a solar cell of the module. The configuration makes it possible to convert a broader spectrum of solar energy into electricity, with a higher certainty, to heighten the module efficiently in photoelectric conversion efficiency.

Furthermore, in the solar cell module of the present invention, the solar cell is preferably a crystal silicon solar cell. By using the solar cell module as a solar cell module in which solar cells as described above are stacked onto each other, the photoelectric conversion efficiency thereof can be more effectively made better. In particular, silicon solar cells have a problem of being low in photoelectric conversion efficiency in the range of wavelengths lower than or equal to a maximum absorption wavelength of silicon, which is 400 nm in an ultraviolet wavelength range. In the present solar cell module, an appropriate use of the above-mentioned polymer fluorescent dye compound, which has an absorption in this wavelength range and can further emit fluorescence at 410 to 560 nm, makes it possible to use light more effectively. If the absorption wavelength range of the polymer fluorescent dye compound is extended into the range of longer wavelengths than the above-mentioned wavelength range, wavelengths which a photoelectric conversion element, such as a solar cell, can originally absorb overlap unfavorably with the absorption wavelengths of the polymer fluorescent dye compound, so that the module may fail in rising in photoelectric conversion efficiency. In the present solar cell module, the use of the above-mentioned polymer fluorescent dye compound makes it possible to control the absorption wavelength of this compound precisely not to cause this problem.

### BRIEF DESCRIPTION OF THE DRAWINGS

FIG. 1 illustrates an example of a solar cell module in which a encapsulant layer of the present invention for solar cells is used.

FIG. 2 illustrates an example of the solar cell module, in which the encapsulant layer of the present invention for solar cells is used.

### MODE FOR CARRYING OUT THE INVENTION

Hereinafter, embodiments of the present invention will be described.

### (Fluorescent Dye Compound)

The fluorescent dye compound of the present invention is a compound represented by the following general formula (III):

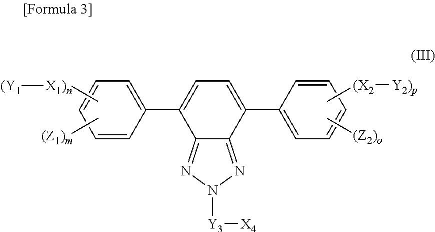

wherein X₁(s) and X₂(s) each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;

Y₁(s), Y₂(s) and Y₃ each independently represent an optionally-substituted alkyl group having 1 to 18 carbon atoms (provided that one or two out of any nonadjacent two of the carbon atoms in the alkyl group may (each) be substituted with an oxygen atom);

X₄ represents a group which contains a carbon-carbon double bond, a group which contains a carbon-carbon triple bond, a hydroxyl group, an ester group, an isocyanate group, an epoxy group, fluorine, chlorine, bromine, iodine, a methanesulfonyl group, p-toluenesulfonyl group, a nitrobenzenesulfonyl group, or a trifluoromethanesulfonyl group;

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the substituents concerned may be the same as or different from each other.

A useful nature of fluorescent (or photo-luminescent) dyes is that these dyes can absorb photons of a light ray having a specified wavelength and can further re-emit the photons with a different wavelength. This phenomenon makes these dyes useful for photoelectromotive industries.

A chromophore represented by the general formula (III) is useful for a fluorescent dye (fluorescent dye compound) in the application of the dye to various articles such as wavelength-converting films. The benzotriazole derivative has a structure illustrated in the general formula (III); thus, this derivative is usable in particular suitably as a monomer for the above-mentioned polymer fluorescent dye compound. As illustrated in this formula, this dye is a benzo heterocyclic compound, more specifically, a novel compound having a benzotriazole structure (benzotriazole derivative). More details and actual examples related to usable types of the compound will be described below although the description does not limit the scope of the present invention. As far as the effects and advantages of the invention are not hindered, the scope of the fluorescent dye compound of the invention also includes any compound in which any atom of the benzotriazole ring of this dye compound is substituted.

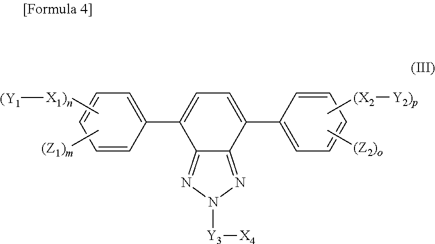

wherein X₁(s) and X₂(s) each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;

Y₁(s), Y₂(s) and Y₃ each independently represent an optionally-substituted alkyl group having 1 to 18 carbon atoms (provided that one or two out of any nonadjacent two of the carbon atoms in the alkyl group may (each) be substituted with an oxygen atom);

X₄ represents a group which contains a carbon-carbon double bond, a group which contains a carbon-carbon triple bond, a hydroxyl group, an ester group, an isocyanate group, an epoxy group, fluorine, chlorine, bromine, iodine, a methanesulfonyl group, p-toluenesulfonyl group, a nitrobenzenesulfonyl group, or a trifluoromethanesulfonyl group;

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the substituents concerned may be the same as or different from each other.

The benzotriazole derivative has a structure illustrated in the general formula (III); thus, this derivative is usable suitably as a monomer for the above-mentioned polymer fluorescent dye compound. The fluorescent dye compound can form a chemical bond to the matrix resin through the X₄ group (by, e.g., radical crosslinkage, nucleophilic substitution reaction, addition reaction or radical polymerization). This matter makes it easy to introduce the fluorescent dye compound into a main chain skeleton of the polymeric structural moiety to produce the form of the so-called pendant to this skeleton, or introduce the fluorescent dye compound into, e.g., a terminal of a main chain skeleton of the polymeric structural moiety to produce the form of an endcap onto the terminal. Furthermore, the use of the fluorescent dye compound of the present invention makes it possible to modify an already existing resin system easily to a polymer fluorescent dye compound suitable for the above-mentioned usage or design the molecule of such a compound by, e.g., copolymerization or addition reaction.

It is also preferred that the benzotriazole derivative has a maximum absorption wavelength in a wavelength range from 300 to 410 nm. When the derivative has the maximum absorption wavelength in this wavelength range, the derivative makes it possible to convert more effectively incident rays having wavelengths which are not easily used (or not usable) for photoelectric conversion by a solar cell into a wavelength range which can be photoelectrically converted by the solar cell or the like.

It is also preferred that the benzotriazole derivative has a maximum fluorescence emission wavelength in a wavelength range from 410 to 560 nm. When the derivative has the maximum fluorescence emission wavelength in this wavelength range, the derivative makes it possible to convert more effectively incident rays having wavelengths which are not easily used (or not usable) for photoelectric conversion by a solar cell into a wavelength range which can be photoelectrically converted by the solar cell.

In the benzotriazole derivative, the symbols X₁(s) and X₂(s) each independently represent —O—, —(C═O)O—, —O(C═O)—, —CH₂O—, —CH₂O(CO)—, —NH(CO)—, —NR—CH₂—, or a single bond. R represents an alkyl group having 1 to 8 carbon atoms. At least one of X₁(s) and X₂(s) is in particular preferably —(C═O)O—, or —O(CO)—. A case where X₁(s) or X₂(s) is/are (each) a single bond denotes that the Y group(s) is/are (each) bonded directly to the benzene ring concerned.

In the benzotriazole derivative, Y₁(s), Y₂(s) and Y₃ each independently represent an optionally-substituted alkyl group having 1 to 18 carbon atoms (provided that one or two out of any nonadjacent two of the carbon atoms in the alkyl group may (each) be substituted with an oxygen atom). The number of carbon atoms of the alkyl group is preferably from 1 to 18, more preferably from 2 to 8. The alkyl group having 1 to 18 carbon atoms may be linear or branched.

Examples of each of the symbols Y₁(s), Y₂(s) and Y₃ include ethyl, propyl, isopropyl, butyl, isobutyl, sec-butyl, t-butyl, pentyl, hexyl, heptyl, 2-ethylhexyl, and octyl. However, each of Y₁(s), Y₂(s) and Y₃ is not limited to these examples.

In the benzotriazole derivative, the symbol X₄ represents a group which contains a carbon-carbon double bond, a group which contains a carbon-carbon triple bond, any other group that can forma covalent bond through an unsaturated bond, a hydroxyl group, an ester group, an isocyanate group, an epoxy group, or any other group that can form a covalent bond by, e.g., condensation reaction or addition reaction; or fluorine, chlorine, bromine, iodine, a methanesulfonyl group, a p-toluenesulfonyl group, a nitrobenzenesulfonyl group, a trifluoromethanesulfonyl group, or any other radical or group that is favorable for substitution reaction as, e.g., a good leaving group. By rendering the X₄ group the functional group described herein, which can form a covalent bond by, e.g., condensation reaction, substitution reaction, addition reaction or polymerization, the benzotriazole derivative can form a chemical bond to the matrix resin (by, e.g., radical crosslinkage, nucleophilic substitution reaction, addition reaction, or polymerization).

In the benzotriazole derivative, the symbol X₄ is preferably —CR′═CH₂, —(C═O)O—CR′═CH₂, —O(C═O)—CR′═CH₂, —CH₂O(CO)—CR′═CH₂, —NH(CO)—CR′═CH₂, or —NR—CH₂—CR′═CH₂ wherein R and R's each independently represent an alkyl group having 1 to 8 carbon atoms. When the derivative has this structure, it becomes easy that the derivative forms a chemical bond, particularly forms a bond by, e.g., radical crosslinkage or radical polymerization reaction, through the X₄ group.

Examples of X₄ include ethenyl, propenyl, isopropenyl, butenyl, isobutenyl, pentenyl, hexenyl, heptenyl, 2-ethylhexenyl, octenyl, 3-allyloxy-2-hydroxypropyl, and 3-allyloxy-2-acetoxypropyl. However, X₄ is not limited to these examples.

In the benzotriazole derivative, Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and m, n, o and p each independently represent an integer of 0 to 4 (provided that m+n is 4 or less, and o+p is 4 or less). The alkyl group having 1 to 18 carbon atoms may be linear or branched. The alkoxy group having 1 to 18 carbon atoms may be linear or branched. The symbols m, n, o and p each independently represent an integer of 0 to 4. The number of carbon atoms of the alkyl group is preferably from 1 to 18, more preferably from 1 to 12, even more preferably from 1 to 8. The number of carbon atoms of the alkoxy group is preferably from 1 to 18, more preferably from 1 to 12, even more preferably from 1 to 8. When m, n, o or p is 2 or more, the plural substituents concerned may be the same as or different from each other.

Examples of the alkyl group as each of Z₁(s) and Z₂(s) include methyl, ethyl, propyl, isopropyl, butyl, isobutyl, sec-butyl, tert-butyl, pentyl, hexyl, heptyl, 2-ethylhexyl, and octyl. However, the alkyl group is not limited to these examples. One or two out of any nonadjacent two of the carbon atoms in the alkyl group may (each) be substituted with an oxygen atom.

The alkoxy group as each of Z₁(s) and Z₂(s) may be a linear or branched alkyl group bonded covalently to the parent molecule through a linkage —O—. Examples of the alkoxy group as each of Z₁(s) and Z₂(s) include methoxy, ethoxy, propoxy, isopropoxy, butoxy, n-butoxy, sec-butoxy, tert-butoxy, pentyloxy, hexyloxy, heptyloxy, 2-ethylhexyloxy, octyloxy, 1-propenyloxy, 2-propenyloxy, butenyloxy, pentenyloxy, hexenyloxy, heptenyloxy, octenyloxy, 3-allyloxy-2-hydroxypropyloxy and 3-allyloxy-2-acetoxypropyloxy. However, the alkoxy group is not limited to these examples. One or two out of any nonadjacent two of the carbon atoms in the alkoxy group may (each) be substituted with an oxygen atom.

The fluoro group as each of Z₁(s) and Z₂(s) may be a group in which hydrogens of an alkyl group are partially or wholly substituted with one or more fluorine atoms. Examples of the fluoro group as each of Z₁(s) and Z₂(s) include trifluoromethyl, and pentafluoroethyl groups. However, the fluoro group is not limited to these groups.

The —COOR¹ group as each of Z₁(s) and Z₂(s) may be a group having an alkyl ester structure. Examples of the —COOR¹ group as each of Z₁(s) and Z₂(s) include methyl ester, ethyl ester, 1-propyl ester, 2-propyl ester, and phenyl ester groups. However, the —COOR¹ group is not limited to these examples.

The —NHCOR² group as each of Z₁(s) and Z₂(s) may be a group having an acylamide structure. Examples of the —NHCOR² group as each of Z₁(s) and Z₂(s) include an acetylamide group, and propionic amide. However, the —NHCOR² group is not limited to these examples.

The symbols m, n, o and p each independently represent an integer of 0 to 4. Specifically, m, n, o and p may each be a value of 0, 1, 2, 3 or 4 provided that m+n is 4 or less, and o+p is 4 or less.

When the word “substituted group” is used in the present specification, the substituted group originates an unsubstituted parent structure in which one or more hydrogen atoms are substituted with one or more different atoms or groups. When the hydrogen(s) concerned is/are substituted, the (one or more) substituents are one or more groups that are individually and independently selected from, for example, the following: C₁-C₆ alkyl, C₁-C₆ alkenyl, C₁-C₆ alkynyl, C₃-C₇ cycloalkyl (which is optionally-substituted with one or more of halo, alkyl, alkoxy, carboxyl, haloalkyl, CN, —SO₂-alkyl, —CF₃, and —OCF₃), cycloalkyl geminally attached, C₁-C₆ heteroalkyl, C₃-C₁₀ heterocycloalkyl (such as tetrahydrofuryl) (which is optionally-substituted with one or more of halo, alkyl, alkoxy, carboxyl, CN, —SO₂-alkyl, —CF₃, and —OCF₃), aryl (which is optionally-substituted with one or more of halo, alkyl, aryl which is optionally-substituted with C₁-C₆ alkyl, arylalkyl, alkoxy, aryloxy, carboxyl, amino, imide, amide (carbamoyl), optionally-substituted cyclic imide, cyclic amide, CN, —NH—C(═O)-alkyl, —CF₃, and —OCF₃), arylalkyl (which is optionally-substituted with one or more of halo, alkyl, alkoxy, aryl, carboxyl, CN, —SO₂-alkyl, —CF₃, and —OCF₃), heteroaryl (which is optionally-substituted with one or more of halo, alkyl, alkoxy, aryl, heteroaryl, aralkyl, carboxyl, CN, —SO₂-alkyl, —CF₃, and —OCF₃), halo (such as chloro, bromo, iodo, or fluoro), cyano, hydroxy, optionally-substituted cyclic imide, amino, imide, amide, —CF₃, C₁-C₆ alkoxy, aryloxy, acyloxy, sulfhydryl (mercapto), halo(C₁-C₆) alkyl, C₁-C₆ alkylthio, arylthio, mono(C₁-C₆)alkylamino, di(C₁-C₆)alkylamino, quaternary ammonium salts, amino(C₁-C₆)alkoxy, hydroxy(C₁-C₆)alkylamino, amino(C₁-C₆)alkylthio, cyanoamino, nitro, carbamoyl, keto(oxy), carbonyl, carboxy, glycolyl, glycyl, hydrazino, guanyl, sulfamyl, sulfonyl, sulfinyl, thiocarbonyl, thiocarboxy, sulfonamide, ester, C-amide, N-amide, N-carbamate, O-carbamate, and urea groups; and any combination of two or more thereof. When any one of the substituents is described as “optionally-substituted” substituent, the substituent may always be substituted with a substituent as described above.

The absorbance of the fluorescent dye compound layer is, for example, preferably from 0.5 to 6, more preferably from 1 to 4, even more preferably from 1 to 3.

The melting point of the fluorescent dye compound is usually preferably from 50 to 200° C. Since the invention of the present application has an advantageous effect that the compound is crosslinked to be restrained from bleeding out, the melting point may be from 20 to 200° C., from 0 to 200° C., or from −20 to 200° C. The use of the benzotriazole derivative having a melting point in any one of these ranges makes it possible to disperse or dissolve the fluorescent dye compound evenly into the system in step of working the compound or the compound-containing composition, for example, the step of heating and kneading the same. When the compound or composition is made into a sheet form, the uniformity of the sheet can in particular easily be obtained. Thus, the compound or composition is particularly good in productivity or workability.

The property of the fluorescent dye (the compound or polymeric compound) in the present invention is not limited only to the property that it is sufficient for the dye to absorb a light ray in a specified wavelength range and further convert the wavelength of the absorbed ray to a longer wavelength to emit the longer wavelength ray. It is preferred that the fluorescent dye in the present application shows no absorption (or less shows an absorption) at longer wavelengths than the maximum absorption wavelength of the dye if possible. About an index thereof, for example, it is desired that the absorbance of the dye at a wavelength 60 nm longer than the maximum absorption wavelength is smaller than the absorbance of the dye at the maximum absorption wavelength.

As a method for synthesizing the above-mentioned fluorescent dye compound, a known method is appropriately usable. Examples of the synthesizing method include a method of causing a bi-substituted benzotriazole (such as halogenated benzotriazole) obtained by substituting leaving groups of, e.g., 4,7-dibromobenztriazole to undergo a coupling reaction with a phenylboronic acid which contains one or more X—Y side-chains (Y₁—X₁ and/or Y₂—X₂); a method of bonding a compound corresponding to a precursor of a phenyl group which contains one or more X—Y side-chains onto the bi-substituted benzotriazole by, e.g., nucleophilic substitution reaction; a method of bonding hydroxyphenylboronic acid onto the bi-substituted benzotriazole, subsequently converting the hydroxyl groups to, e.g., alkoxy groups or ester groups, and then introducing one or more X—Y groups to the resultant; a method of using a metallic catalyst to attain the coupling; a method of converting alkoxy groups as the side chains partially to carbon-carbon double bonds; and a method in which at a time before or after the introduction of the X—Y side chain(s), or at a time simultaneous with the introduction, one or more Y₃—X₄ groups are introduced to the compound concerned.

For example, the following methods are given as particularly preferred and easy methods: a method of esterifying, with an unsaturated acid such as oleic acid, a hydroxyphenylbenzotriazole derivative in which a benzene ring adjacent to a benzotriazole skeleton has a phenolic hydroxyl group, thereby being condensed with the acid (in which a condensing agent may be appropriately used); a method of esterifying, with an unsaturated aliphatic alcohol, a carboxyphenylbenzotriazole derivative in which a benzene ring adjacent to a benzotriazole skeleton has a carboxyl group, thereby being condensed with the alcohol (in which a condensing agent may be appropriately used); and a method of using an alkylation reaction to link a halide or glycidyl compound which has an unsaturated bond to a hydroxyphenylbenzotriazole derivative in which a benzene ring adjacent to a benzotriazole skeleton has a phenolic hydroxyl group.

Furthermore, the fluorescent dye compound has the above-mentioned reactive moiety (moiety reactive with a polymeric matrix or the like) so that the compound is fixable to the matrix polymer. In particular, in the step of curing the above-mentioned wavelength-converting encapsulant composition or wavelength-converting encapsulant layer, the fluorescent dye can be easily and simultaneously fixed thereto; thus, the fixation is very good also for industrial processes. When or after the wavelength-converting encapsulant layer is formed, or when or after the module is mounted, the fixation onto the matrix polymer can be generally attained by, for example, light radiating treatment, heating treatment for the fixation, light radiating treatment, or a different heating treatment. The fixation may be partially or wholly performed at the stage of the wavelength-converting encapsulant composition.

### (Polymer Fluorescent Dye Compound)

The polymer fluorescent dye compound of the present invention is represented by the following formula (I):

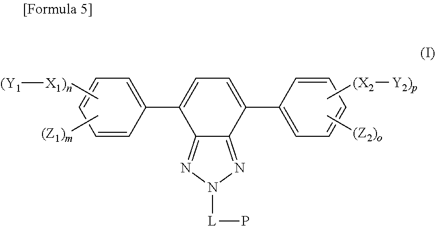

wherein X₁(s) and X₂(s) each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;

Y₁(s) and Y₂(s) each independently represent an optionally-substituted alkyl group having 1 to 18 carbon atoms (provided that one or two out of any nonadjacent two of the carbon atoms in the alkyl group may (each) be substituted with an oxygen atom);

P represents a polymeric structural moiety;

L represents a linker structural moiety through which a benzotriazole ring of the compound and the polymeric structural moiety are bonded to each other by a covalent bond;

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the substituents concerned may be the same as or different from each other.

The chromophore represented by the general formula (I) is useful for a fluorescent dye (polymer fluorescent dye compound) in the application of the dye to various articles such as wavelength-converting films. As illustrated in the formula illustrated above, this dye is a benzo heterocyclic compound, more specifically, a novel polymeric compound having a benzotriazole structure (benzotriazole-structure-containing polymer). As far as the effects and advantages of the present invention are not hindered, the scope of the polymer fluorescent dye compound of the invention also includes any compound in which any atom of the benzotriazole ring of this dye compound is substituted.

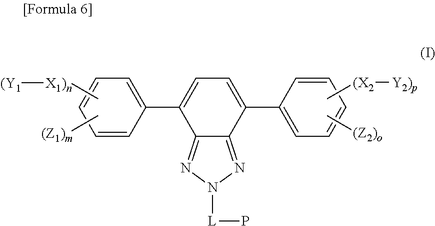

wherein X₁ (s) and X₂ (s) each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;

Y₁(s) and Y₂(s) each independently represent an optionally-substituted alkyl group having 1 to 18 carbon atoms (provided that one or two out of any nonadjacent two of the carbon atoms in the alkyl group may (each) be substituted with an oxygen atom);

P represents a polymeric structural moiety;

L represents a linker structural moiety through which a benzotriazole ring of the compound and the polymeric structural moiety are bonded to each other by a covalent bond;

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the substituents concerned may be the same as or different from each other.

The polymer fluorescent dye compound of the present invention has the structure represented by the general formula (I). Thus, the compound can be an excellent fluorescent dye compound having a high workability, desired optical properties (such as a high quantum yield) and a good light stability (chemical and physical stability). About the polymer fluorescent dye compound, particularly, its specific benzotriazole moiety effecting as a fluorescent dye is chemically linked to its polymeric structural moiety, whereby this compound is restrained from being shifted in the matrix resin. Consequently, the polymer fluorescent dye compound dispersed in the matrix resin can easily give a stable and uniform encapsulant composition (and layer) without being precipitated even in a long-term storage test.

In the polymer fluorescent dye compound, the symbol L represents a linker structural moiety through which the benzotriazole ring and the polymeric structural moiety are bonded to each other by a covalent bond. It is preferred that the symbol L is combined neither with the benzotriazole ring nor with the polymeric structural moiety for the formation of any conjugated bond. However, L may have a conjugated bond (for example, a carbon-carbon double bond) at a position of L where L is combined neither with the benzotriazole ring nor with the polymeric structural moiety for the formation of any conjugated bond.

The polymer fluorescent dye compound is preferably represented by the following general formula (II):

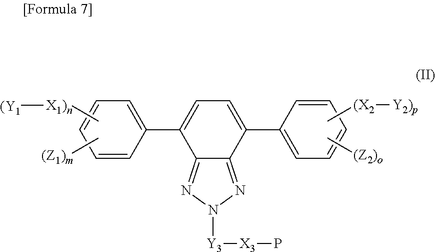

wherein X₁(s), X₂(s) and X₃ each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;

Y₁(s), Y₂(s) and Y₃ each independently represent an optionally-substituted alkyl group having 1 to 18 carbon atoms (provided that one or two out of any nonadjacent two of the carbon atoms in the alkyl group may (each) be substituted with an oxygen atom);

P represents a polymeric structural moiety;

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the substituents concerned may be the same as or different from each other.

The description about the benzotriazole skeleton in the polymer fluorescent dye compound, and the symbols X₁(s), X₂(s), Y₁(s), Y₂(s), Y₃, Z₁(s), Z₂(s), m, n, o and p and other symbols therein are fittingly the same as in the general formula (III) of the fluorescent dye compound.

In the polymer fluorescent dye compound, the symbol X₃ each independently represents —O—, —(C═O)O—, —O(C═O)—, —CH₂O—, —CH₂O(CO)—, —NH(CO)—, —NR—CH₂—, or a single bond. R represents an alkyl group having 1 to 8 carbon atoms. X₃ is preferably —(C═O)O— or —O(CO)—. A case where X₃ is a single bond denotes that Y₃ is bonded directly to the polymeric structural moiety P.

In the polymer fluorescent dye compound, the symbol P is preferably polyethylene terephthalate, poly(meth)acrylate, polyvinyl acetate, polyethylene tetrafluoroethylene, polyimide, amorphous polycarbonate, siloxane sol-gel, polyurethane, polystyrene, polyethersulfone, polyacrylate, epoxy resin, polyethylene, polypropylene, poly(ethylene-vinyl acetate) or silicone resin.

The absorbance of the polymer fluorescent dye compound is, for example, preferably from 0.5 to 6, more preferably from 1 to 4, even more preferably from 1 to 3.

Usually, the melting point of the polymer fluorescent dye compound is preferably from 50 to 200° C. In the invention of the present application, the dye compound has been made high in molecular weight, whereby this compound has an advantageous effect of decreasing the bleeding-out of the compound; thus, the melting point may be from 20 to 200° C., from 0 to 200° C., or from −20 to 200° C. The polymer fluorescent dye compound having a melting point in any one of these ranges can be a compound which can be uniformly dispersed or dissolved in the system in the step of working the compound or the compound-containing composition, for example, the step of heating and kneading the same. When the compound or composition is made, particularly, into a sheet, the sheet easily gains uniformity to be excellent in productivity and workability.

The method for synthesizing the polymer fluorescent dye compound may be, for example, a method of subjecting a monomer having a specific benzotriazole structure to polymerization reaction; a method of subjecting the monomer and an optional copolymerizable monomer to copolymerization reaction; or a method of forming a covalent bond fittingly to an already produced polymer, thereby introducing a specific benzotriazole structure to the polymer (addition-manner introduction method). In the synthesis method, the use of the fluorescent dye compound of the present invention, which is represented by the formula (III), makes it possible to synthesize a desired polymer fluorescent dye compound easily.

When the polymerization or copolymerization reaction is conducted, a known polymer-synthesizing method is appropriately usable. The method is, for example, a method of subjecting the monomer of the general formula (III) according to the present invention to homo-polymerization, or a method of subjecting the monomer of the general formula (III) and a different monomer to random-, graft-, cross-, or block-copolymerization. The polymerization or copolymerization reaction makes use of, e.g., radical polymerization (cation, anion, each living, and others), ion polymerization, addition polymerization (polyaddition), condensation polymerization (polycondensation), cyclization polymerization, or ring-opening polymerization. The polymerization or copolymerization reaction makes use of, e.g., a synthesis manner in an organic solvent system or aqueous solution system, or in an emulsion state or suspension state.

It is preferred in the copolymerization reaction to use a monomer for forming the structure P as the different monomer, which is polymerized together with the monomer of the general formula (III) or any other monomer having a benzotriazole structure. The different monomer is preferably, for example, an ethylene terephthalate derivative, (meth)acrylate derivative, vinyl acetate derivative, ethylene tetrafluoroethylene derivative, styrene derivative, ethersulfone derivative, arylate derivative, epoxy derivative, ethylene derivative, propylene derivative or vinyl derivative. A (meth)acrylic monomer or (meth)acrylic oligomer is particularly preferred, which turns to a vinyl resin, particularly, an acrylic resin or methacrylic resin when subjected to polymerization reaction. The above-mentioned monomers may be used singly or in the form of a mixture of two or more thereof.

Examples of the different monomer include acrylic acid, methacrylic acid, methyl acrylate, methyl methacrylate, ethyl acrylate, ethyl methacrylate, butyl acrylate, butyl methacrylate, 2-ethylhexyl acrylate, 2-ethylhexyl methacrylate, any other alkyl (meth)acrylate, cyclohexyl acrylate, cyclohexyl methacrylate, phenyl acrylate, phenyl methacrylate, benzyl acrylate, benzyl methacrylate, styrene, α-methylstyrene, vinyltoluene, acrylamide, diacetoneacrylamide, acrylonitrile, methacrylonitrile, maleic anhydride, phenylmaleimide, and cyclohexylmaleimide. Other examples thereof include any alkyl (meth)acrylate in which the alkyl group is substituted with, e.g., a hydroxyl group, an epoxy group, or a halogen radical. About the alkyl (meth)acrylate, the number of carbon atoms of the alkyl group of the ester moiety therein is preferably from 1 to 18, more preferably from 1 to 8 carbon atoms. These compounds may be used singly, or in the form of a mixture of two or more thereof.

At the time of conducting the copolymerization reaction, about the polymer fluorescent dye compound, the monomer of the general formula (III), or any other monomer having a benzotriazole structure is used preferably in an amount of 0.001 to 100 parts by weight for 100 parts by weight of the entire monomer components. The monomer may be used in an amount of 0.001 to 50 parts by weight, in an amount of 0.005 to 30 parts by weight, or in an amount of 0.01 to 10 parts by weight.

At the time of conducting the polymerization reaction or the copolymerization reaction, the polymerization can be attained, for example, by adding a thermopolymerization initiator or photopolymerization initiator to the monomer components, and then heating the resultant or radiating light to the resultant.

The thermopolymerization initiator may be an appropriate known peroxide. Examples of the polymerization initiator include 2,5-dimethylhexane-2,5-dihydroperoxide, 2,5-dimethyl-2,5-di(t-butylperoxy)hexane-3, di-t-butylperoxide, dicumylperoxide, 2,5-dimethyl-2,5-di(t-butylperoxy)hexane, dicumylperoxide, α,α′-bis(t-butylperoxyisopropyl)benzene, n-butyl-4,4-bis(t-butylperoxy)butane, 2,2-bis(t-butylperoxy)butane, 1,1-bis(t-butylperoxy)cyclohexane, 1,1-bis(t-butylperoxy)3,3,5-trimethylcyclohexane, t-butyl peroxybenzoate, and benzoylperoxide. These compounds may be used singly, or in the form of a mixture of two or more thereof.

The blend amount of the thermopolymerization initiator may be, for example, in an amount of 0.1 to 5 parts by weight for 100 parts by weight of the monomer components.

The above-mentioned photopolymerization initiator may be an appropriate known photopolymerization initiator that produces free radicals by ultraviolet rays or visible rays. Examples of the photopolymerization initiator include benzoin ethers such as benzoin methyl ether, benzoin ethyl ether, benzoin isopropyl ether, benzoin isobutyl ether, and benzoin phenyl ether; benzophenones such as benzophenone, N,N′-tetramethyl-4,4′-diaminobenzophenone (Michler's ketone), and N,N′-tetraethyl-4,4′-diaminobenzophenone; benzyl ketals such as benzyl dimethyl ketal (IRGACURE 651, manufactured by Ciba Japan K.K.), and benzyl diethyl ketal; acetophenones such as 2,2-dimethoxy-2-phenylacetophenone, p-tert-butyldichloroacetophenone, and p-dimethylaminoacetophenone; xanthones such as 2,4-dimethylthioxanthone, and 2,4-diisopropylthioxanthone; and hydroxycyclohexyl phenyl ketone (IRGACURE 184, manufactured by Ciba Specialty Chemicals, Inc.), 1-(4-isopropylphenyl)-2-hydroxy-2-methylpropane-1-one (DAROCURE 1116, manufactured by Ciba Japan K.K.), and 2-hydroxy-2-methyl-1-phenylpropane-1-one (DAROCURE 1173, manufactured by Merck & Co., Inc.). These initiators may be used singly, or in the form of a mixture of two or more thereof.

The photopolymerization initiator may be, for example, a combination of a 2,4,5-triallylimidazole dimer with 2-mercaptobenzoxazole, leuco crystal violet, or tris(4-diethylamino-2-methylphenyl)methane. A known additive, for example, a tertiary amine such as triethanolamine for benzophenone may be appropriately used.

The blend amount of the photopolymerization initiator may be, for example, from 0.1 to 5 parts by weight for 100 parts by weight of the monomer components.

When the above-mentioned addition-manner introduction method is conducted, a known organic synthesis method is appropriately usable. The method is, for example, a method of subjecting the fluorescent dye compound of the general formula (III) according to the present invention to, e.g., a condensation reaction, addition reaction or substitution reaction to form covalent bonds. Furthermore, the method may be, for example, a method of introducing the fluorescent dye compound into an already produced polymer to produce the form of the so-called pendant to a main chain skeleton of the polymeric structural moiety of the polymer; or a method of introducing the fluorescent dye compound into, e.g., a terminal of a main chain skeleton of the polymeric structural moiety to produce the form of an endcap onto the terminal.

Examples of the addition-manner introduction method include esterification reaction based on condensation reaction between a carboxylic acid of a polymeric main chain and a functional moiety (benzotriazole skeleton) having a hydroxyl group or a halogen radical; amidation reaction based on condensation reaction between a carboxylic acid of a polymeric main chain and a functional moiety having an amino group; esterification reaction based on condensation reaction between a hydroxyl group of a polymeric main chain and a functional moiety having a carboxylic acid; etherification reaction based on alkylation reaction between a hydroxyl group of a polymeric main chain and a functional moiety having a halogen radical; alkyl amination reaction based on alkylation reaction between an amino group of a polymeric main chain and a functional moiety having a halogen radical; etherification reaction based on alkylation reaction between a phenolic group of a polymeric main chain and a functional moiety having a halogen radical; and graft polymerization onto any polymeric structure. However, the addition-manner introduction method is not limited to these examples.

In the addition-manner introduction method, as the polymer having the already formed polymeric structure, for example, the following may be likewise used: a copolymer having a polyethylene moiety and a polyacrylate moiety, a copolymer having a polyethylene moiety and a polyvinyl alcohol moiety, a copolymer having a polyethylene moiety and a polyacyloxyvinyl moiety, or a copolymer made of monomer units of different species.

About the polymer fluorescent dye compound, the number-average molecular weight of the polymer may be from 500 to 10000, from 800 to 50000, or from 1000 to 100000. The number-average molecular weight is based on a value measured by GPC (in terms of that of polystyrene).

About the polymer fluorescent dye compound, the presence of the benzotriazole structure, the content by percentage thereof and others can be guessed or checked by detecting and analyzing its secondary ions even when this compound is at any one of the stage of the fluorescent dye compound, and the stages of a wavelength-converting encapsulant composition, a wavelength-converting encapsulant layer and a solar cell module each as described above. For example, about the fluorescent dye compound, the following secondary ions can be detected: a negative secondary ion at 382.2 that has a peak originating from a benzotriazole structure obtained by the cleavage of a bond between N—Y₃ in the general formula (I).

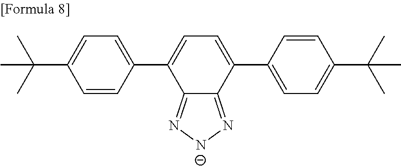

The above-mentioned wavelength-converting encapsulant layer makes use of the wavelength-converting encapsulant composition, which contains the polymer fluorescent dye compound having a reaction moiety as described above, and others. Thus, when the reactive moiety remains in the polymer fluorescent dye compound, the following can be attained in the step of curing the wavelength-converting encapsulant composition or the wavelength-converting encapsulant layer: to its matrix polymer, the fluorescent dye can be easily and simultaneously fixed. This matter is very good also for industrial processes. When or after the wavelength-converting encapsulant layer is formed, or when or after the module is mounted, the fixation onto the matrix polymer can be generally attained by, for example, light radiating treatment, heating treatment for the fixation, light radiating treatment, or a different heating treatment. The fixation may be partially or wholly performed at the stage of the wavelength-converting encapsulant composition.

### (Wavelength-Converting Encapsulant Composition)

The wavelength-converting encapsulant composition of the present invention has a wavelength-converting function. The wavelength-converting encapsulant composition is preferably a composition for converting the wavelength of a light ray radiated into the composition to a longer wavelength. The wavelength-converting encapsulant composition can be formed, for example, by dispersing the above-defined polymer fluorescent dye compound, which has a wavelength-converting function, and some other into an optically transparent matrix resin. About the wavelength-converting encapsulant composition, the polymer fluorescent dye compound may be used as a matrix material of the composition without using the matrix resin described just above.

In the wavelength-converting encapsulant composition of the present invention, it is preferred to use an optically transparent matrix resin. Examples of the matrix resin include polyethylene terephthalate, any poly(meth)acrylate, any polyvinyl acetate, any polyolefin such as polyethylenetetrafluoroethylene, polyimide, amorphous polycarbonate, siloxane sol-gel, polyurethane, polystyrene, polyethersulfone, polyarylate, epoxy resin, and silicone resin. These resins may be used singly, or in the form of a mixture of two or more thereof.

Examples of the above-mentioned poly(meth)acrylate include polyacrylate and polymethacrylate, an example of which is (meth)acrylate resin. Examples of the polyolefin resin include polyethylene, polypropylene, and polybutadiene. Examples of the polyvinyl acetate include polyvinyl formal, polyvinyl butyral (PVB resin), and modified PVB.

Examples of a constituent monomer for the (meth)acrylate resin described just above include alkyl (meth)acrylates such as methyl acrylate, methyl methacrylate, ethyl acrylate, ethyl methacrylate, butyl acrylate, butyl methacrylate, 2-ethylhexyl acrylate, and 2-ethylhexyl methacrylate; and cyclohexyl acrylate, cyclohexyl methacrylate, phenyl acrylate, phenyl methacrylate, benzyl acrylate, and benzyl methacrylate. The constituent monomer may also be any alkyl (meth)acrylate in which any one of the alkyl groups described just above is substituted with, e.g., a hydroxyl group, an epoxy group, or a halogen radical. These compounds may be used singly, or in the form of a mixture of two or more thereof.

In the (meth)acrylate, the number of carbon atoms of the alkyl group in its ester moiety is preferably from 1 to 18, more preferably from 1 to 8.

The above-mentioned (meth)acrylate resin may be rendered a copolymer by using, besides the (meth)acrylate, an unsaturated monomer copolymerizable with the (meth)acrylate.

Examples of the unsaturated monomer include unsaturated organic acids such as methacrylic acid and acrylic acid, styrene, a-methylstyrene, acrylamide, diacetoneacrylamide, acrylonitrile, methacrylonitrile, maleic anhydride, phenylmaleimide, and cyclohexylmaleimide. These unsaturated monomers may be used singly, or in the form of a mixture of two or more thereof.

Out of species of the (meth)acrylate, particularly preferred are methyl acrylate, ethyl acrylate, isobutyl acrylate, n-butyl acrylate, 2-ethylhexyl acrylate, methyl methacrylate, isobutyl methacrylate, n-butyl methacrylate, and 2-ethylhexyl methacrylate; and any alkyl (meth)acrylate in which the functional group of any one of these (meth)acrylates is substituted. Methyl methacrylate is a more preferred example from the viewpoint of durability and versatility.

The copolymer made from the (meth)acrylate and the unsaturated monomer is, for example, (meth)acrylate-styrene copolymer, or poly(ethylene-vinyl acetate). Out of these examples, poly(ethylene-vinyl acetate) is preferred from the viewpoint of moisture resistance, versatility, and costs. Moreover, any (meth)acrylate is preferred from the viewpoint of durability and surface hardness. Furthermore, from the above-mentioned individual viewpoints, it is preferred to use the poly(ethylene-vinyl acetate) and the (meth)acrylate in combination.

About the poly(ethylene-vinyl acetate), the content by proportion of the vinyl acetate units is from 10 to 35 parts by weight, more preferably from 20 to 30 parts by weight for 100 parts by weight of the poly(ethylene-vinyl acetate). Any one of these contents by proportion is preferred from the viewpoint of a uniform dispersibility of, e.g., a rare earth complex into the matrix resin.

When the poly(ethylene-vinyl acetate) is used as the optically transparent matrix resin, a commercially available product is fittingly usable. Examples of the commercially available product of the poly(ethylene-vinyl acetate) include ULTRACENE (manufactured by Tosoh Corp.), EVAFLEX (manufactured by Du Pont-Mitsui Polychemicals Co., Ltd.), SUNTEC EVA (manufactured by Asahi Kasei Chemicals Corp.), UBE EVA copolymer (manufactured by Ube-Maruzen Polyethylene Co., Ltd.), EVATATE (manufactured by Sumitomo Chemical Co., Ltd.), NOVATEC EVA (manufactured by Japan Polyethylene Corp.), SUMITATE (manufactured by Sumitomo Chemical Co., Ltd.), and NIPOFLEX (manufactured by Tosoh Corp.).

A crosslinking monomer may be added to the matrix resin to render this resin a resin having a crosslinked structure.

Examples of the crosslinking monomer include dicyclopentenyl (meth)acrylate, tetrahydrofurfuryl (meth)acrylate, benzyl (meth)acrylate, compounds each obtained by causing an α,β-unsaturated carboxylic acid to react with a polyhydric alcohol (for example, polyethylene glycol di(meth)acrylate (the number of ethylene groups: 2 to 14), trimethylolpropane di(meth)acrylate, trimethylolpropane tri(meth)acrylate, trimethylolpropane ethoxytri(meth)acrylate, trimethylolpropane propoxytri(meth)acrylate, tetramethylolmethane tri(meth)acrylate, tetramethylolmethane tetra(meth)acrylate, polypropylene glycol di(meth)acrylate (the number of propylene groups: 2 to 14), dipentaerythritol penta(meth)acrylate, dipentaerythritol hexa(meth)acrylate, bisphenol A polyoxyethylene di(meth)acrylate, bisphenol A dioxyethylene di(meth)acrylate, bisphenol A trioxyethylene di(meth)acrylate, and bisphenol A decaoxyethylene di(meth)acrylate), compounds each obtained by adding an α,β-unsaturated carboxylic acid to a glycidyl-group-containing compound (for example, trimethylolpropane triglycidyl ether triacrylate, and bisphenol A diglycidyl ether diacrylate), esterified products each made from a polybasic carboxylic acid (such as phthalic anhydride) and a substance having a hydroxyl group and an ethylenical unsaturated group (such as β-hydroxyethyl (meth)acrylate), alkyl esters of acrylic acid or methacrylic acid (for example, methyl (meth)acrylate, ethyl (meth)acrylate, butyl (meth)acrylate, and 2-ethylhexyl (meth)acrylate), and urethane (meth)acrylates (for example, a reactant made from tolylene diisocyanate and 2-hydroxyethyl (meth)acrylate, and a reactant made from trimethylhexamethylene diisocyanate, cyclohexanedimethanol, and 2-hydroxyethyl (meth)acrylate). These crosslinking monomers may be used singly, or in the form of a mixture of two or more thereof. Out of these crosslinking monomers, preferred are trimethylolpropane tri(meth)acrylate, dipentaerythritol tetra(meth)acrylate, dipentaerythritol hexa(meth)acrylate, and bisphenol A polyoxyethylene dimethacrylate.

When the matrix resin containing the crosslinking resin is used, a crosslinked structure can be formed, for example, by adding the thermopolymerization initiator or photopolymerization initiator to the crosslinking monomer, and then heating the resultant or radiating light to the resultant to be polymerized and crosslinked. The polymerization initiator can contribute to the formation of a crosslinked structure of the fluorescent dye compound and the matrix resin through the carbon-carbon double bond of this dye compound according to circumstances.

The thermopolymerization initiator may be an appropriate known peroxide. Examples of the thermopolymerization initiator include 2,5-dimethylhexane-2,5-dihydroperoxide, 2,5-dimethyl-2,5-di(t-butylperoxy)hexane-3, di-t-butylperoxide, dicumylperoxide, 2,5-dimethyl-2,5-di(t-butylperoxy)hexane, dicumylperoxide, α,α′-bis(t-butylperoxyisopropyl)benzene, n-butyl-4,4-bis(t-butylperoxy)butane, 2,2-bis(t-butylperoxy)butane, 1,1-bis(t-butylperoxy)cyclohexane, 1,1-bis(t-butylperoxy)3,3,5-trimethylcyclohexane, t-butyl peroxybenzoate, and benzoylperoxide. These compounds may be used singly, or in the form of a mixture of two or more thereof.

The blend amount of the thermopolymerization initiator may be, for example, in an amount of 0.1 to 5 parts by weight for 100 parts by weight of the matrix resin.

The above-mentioned photopolymerization initiator may be an appropriate known photopolymerization initiator that produces free radicals by ultraviolet rays or visible rays. Examples of the photopolymerization initiator include benzoin ethers such as benzoin methyl ether, benzoin ethyl ether, benzoin isopropyl ether, benzoin isobutyl ether, and benzoin phenyl ether; benzophenones such as benzophenone, N,N′-tetramethyl-4,4′-diaminobenzophenone (Michler's ketone), and N,N′-tetraethyl-4,4′-diaminobenzophenone; benzyl ketals such as benzyl dimethyl ketal (IRGACURE 651, manufactured by Ciba Japan K.K.), and benzyl diethyl ketal; acetophenones such as 2,2-dimethoxy-2-phenylacetophenone, p-tert-butyldichloroacetophenone, and p-dimethylaminoacetophenone; xanthones such as 2,4-dimethylthioxanthone, and 2,4-diisopropylthioxanthone; and hydroxycyclohexyl phenyl ketone (IRGACURE 184, manufactured by Ciba Specialty Chemicals, Inc.), 1-(4-isopropylphenyl)-2-hydroxy-2-methylpropane-1-one (DAROCURE 1116, manufactured by Ciba Japan K.K.), and 2-hydroxy-2-methyl-1-phenylpropane-1-one (DAROCURE 1173, manufactured by Merck & Co., Inc.). These initiators may be used singly, or in the form of a mixture of two or more thereof.

The photopolymerization initiator may be, for example, a combination of a 2,4,5-triallylimidazole dimer with 2-mercaptobenzoxazole, leuco crystal violet, or tris(4-diethylamino-2-methylphenyl)methane. A known additive, for example, a tertiary amine such as triethanolamine for benzophenone may be appropriately used.

The blend amount of the photopolymerization initiator is, for example, from 0.1 to 5 parts by weight for 100 parts by weight of the matrix resin.

The refractive index of the matrix resin ranges, for example, from 1.4 to 1.7, from 1.45 to 1.65 or from 1.45 to 1.55. In some embodiments, the refractive index of the polymer matrix material is 1.5.

The fluorescent dye compound is preferably a compound which absorbs light rays having wavelengths of 300 to 410 nm more largely than light rays having wavelengths more than 410 nm. A reason therefor is as follows: in a case where the compound absorbs light rays having wavelengths more than 410 nm more largely even when the compound absorbs light rays having wavelengths of 410 nm or less, the total quantity of light rays usable in the photoelectric conversion layer is unfavorably decreased. When the compound absorbs light rays having wavelengths of 300 to 410 nm more largely than light rays having wavelengths more than 410 nm, light rays the wavelength of which has been converted also come to be usable without decreasing light rays (direct rays) usable in the photoelectric conversion layer, so that the total quantity of light rays usable in the photoelectric conversion layer can be increased.

The wavelength-converting encapsulant composition can be produced, for example, by dispersing the polymer fluorescent dye compound, which has a wavelength-converting function, into the matrix resin, as described above. In the wavelength-converting encapsulant composition, instead of the matrix resin, the polymer fluorescent dye compound may be used as a matrix material of the composition.

In the wavelength-converting encapsulant composition of the present invention, the polymer fluorescent dye compound is contained in a proportion preferably from 0.05 to 100% by weight. The proportion may be from 0.01 to 80% by weight, from 0.1 to 50% by weight, from 1 to 30% by weight, or from 1 to 10% by weight.

In the wavelength-converting encapsulant composition of the present invention, the polymer fluorescent dye compound is contained in an amount ranging from 0.01 to 100 parts by weight for 100 parts by weight of the resin matrix. The amount may be from 0.1 to 50 parts by weight, from 1 to 20 parts by weight, or from 1 to 10 parts by weight.

The wavelength-converting encapsulant composition may appropriately contain an additive as far as a desired performance thereof is not damaged. Examples of the additive include a thermoplastic polymer, an antioxidant, an ultraviolet preventing agent, a light stabilizer, an organic peroxide, a filler, a plasticizer, a silane coupling agent, an acid receiving agent, and clay. These may be used singly or in the form of a mixture of two or more thereof.

In order to produce the wavelength-converting encapsulant composition, it is sufficient to perform the production in accordance with a known method. The method is, for example, a method of heating and kneading the above-mentioned individual materials to be mixed with each other in a known manner, using, e.g., a super mixer (high-velocity flowing mixer), a roll mill, or a Plastomill. The production may be performed continuously to the production of the above-mentioned wavelength-converting encapsulant layer.

### (Wavelength-Converting Encapsulant Layer)

The wavelength-converting encapsulant layer of the present invention is a layer formed, using the above-defined wavelength-converting encapsulant composition.

In order to produce the wavelength-converting encapsulant layer, it is sufficient to perform the production in accordance with a known method. This layer can be appropriately produced by, for example, a method of heating and kneading the above-mentioned individual materials to be mixed with each other in a known manner, using, e.g., a super mixer (high-velocity flowing mixer), a roll mill or a Plastomill, and then shaping the resultant composition into a sheet product by, e.g., an ordinary extrusion, calendering, or vacuum hot press. Moreover, this layer can be produced by forming the same layer as described just above onto, e.g., a PET film, and then transferring this layer onto a surface protective layer. Furthermore, a method is usable in which a hot melt applicator is used to knead and melt the composition simultaneously with the application of the composition.

More specifically, for example, the wavelength-converting encapsulant composition, which contains the matrix resin, the polymer fluorescent dye compound and others, may be applied, as it is, onto, e.g., a surface protective layer or a separator; or this material may be applied in the state of being mixed with a different material into a mixed composition. The wavelength-converting encapsulant composition may be formed by, e.g., vapor deposition, sputtering or an aerosol deposition method.

In the case of the application of the mixed composition, the melting point of the matrix resin is preferably from 50 to 250° C., more preferably from 50 to 200° C., even more preferably from 50 to 180° C., considering the workability of the composition. When the melting point of the wavelength-converting encapsulant composition is, for example, from 50 to 250° C., the kneading and melting temperature of the composition, and the application temperature thereof are each preferably a temperature of the melting point plus a temperature of 30 to 100° C.

In some embodiments, the wavelength-converting encapsulant layer is produced into a thin film structure through the following steps: step (i) of preparing a polymer solution in which a polymer (matrix resin) powder is dissolved in a solvent (such as tetrachloroethylene (TCE), cyclopentanone, or dioxane) to give a predetermined proportion; step (ii) of preparing a luminescent dye (such as a polymer fluorescent dye compound) containing a polymer mixture by mixing the polymer solution with the luminescent dye at a predetermined ratio by weight therebetween to yield a dye-containing polymer solution; step (iii) of forming a dye/polymer thin film by causing the dye-containing polymer solution to flow directly onto a glass substrate, subsequently treating the substrate thermally at temperatures from room temperature to at highest 100° C. over 2 hours, and then heating the resultant in a vacuum at 130° C. all night to remove a remaining fragment of the solvent completely; step (iv) of peeling off the dye/polymer thin film in water and then drying the resultant self-standing type polymer film completely before the thin film structure is used; and step (v) of being able to control the thickness of the film by changing the concentration in the dye/polymer solution, and the evaporation velocity thereof.

If the melting point of the polymer fluorescent dye compound is excessively high in the case of working the workpiece of the thin film structure by, e.g., the heating and kneading treatment, the compound is not evenly dispersed or dissolved with ease into the system (for example, in the polymeric matrix). Thus, it is difficult to disperse the dye evenly in the resultant sheet. It is therefore preferred that the melting point of the polymer fluorescent dye compound is 200° C. or lower, desirably 180° C. or lower, more desirably 150° C. or lower. However, if the melting point is too low, there may be caused inconveniences, for example, the bleeding-out of the dye. Thus, a polymer fluorescent dye compound having a melting point of 50° C. or lower may be poor in the above-mentioned steps. Thus, the melting point is preferably 50° C. or higher, more preferably 60° C. or higher, even more preferably 70° C. or higher. The use of a chromophore described above in the present invention makes it easy that when the composition of the invention is made, particularly, into a sheet, the sheet gains uniformity to be especially good in productivity and workability.

The thickness of the wavelength-converting encapsulant layer is preferably from 20 to 2000 μm, more preferably from 50 to 1000 μm, even more preferably from 100 to 800 μm. If the thickness is smaller than 5 μm, this layer does not easily express a wavelength-converting function. In the meantime, if the thickness is larger than 700 μm, this layer is disadvantageous for costs. The use of the wavelength-converting encapsulant layer makes it possible to prevent the dye compound from bleeding out, or decrease the bleeding-out largely even when the wavelength-converting encapsulant layer is rendered, for example, a thin layer of 600 μm thickness.

The optical thickness (absorbance) of the wavelength-converting encapsulant layer is preferably from 0.5 to 6, more preferably from 1 to 4, even more preferably from 1 to 3. If the absorbance is low, this layer does not easily express a wavelength-converting function. In the meantime, if the absorbance is too large, a disadvantage is produced for costs. The absorbance is a value calculated out in accordance with the Lambert-Beer law.

### (Solar Cell Module)

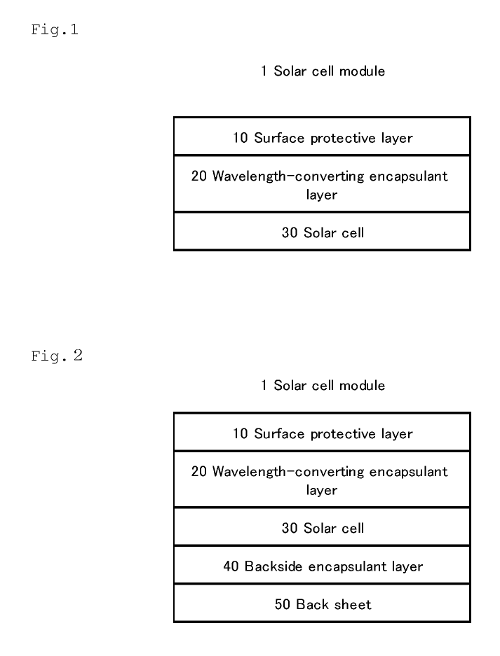

A solar cell module 1 of the present invention includes a surface protective layer 10, a layer 20 for a solar cell that is the above-defined encapsulant layer, and a solar cell 30. A simple schematic view thereof is illustrated, as an example, in each of FIGS. 1 and 2. However, the present invention is not limited to these examples. The solar cell may further have, on the rear surface side thereof, another encapsulant layer 40, and a back sheet 50 as the case may be. As far as the function of the encapsulant layer for a solar cell is not damaged, between any two of these layers a different layer such as an adhesive layer or a pressure-sensitive adhesive layer may fittingly be interposed. The encapsulant layer for the rear surface may be a wavelength-converting encapsulant layer of the present invention as the case may be.

The solar cell module has the above-defined wavelength-converting encapsulant layer to make it possible to convert wavelengths which do not usually contribute to photoelectric conversion to wavelengths which can contribute to photoelectric conversion. Specifically, a certain wavelength can be converted to a longer wavelength. For example, wavelengths shorter than 380 nm can be converted to wavelengths of 380 nm and more. The solar cell module is a module converting, in particular, ultraviolet ray wavelengths (of 200 to 365 nm) to visible ray wavelengths (of 400 to 800 nm). This range of wavelengths contributing to photoelectric conversion is varied in accordance with the species of the solar cell. Even when this solar cell is, for example, a silicon solar cell, the range is varied in accordance with the crystal form of the used silicon. In the case of, for example, an amorphous silicon solar cell and a polycrystal silicon solar cell, the respective photoelectric-conversion-contributing wavelength ranges thereof would be from 400 to 700 nm, and from about 600 to 1100 nm. Thus, wavelengths contributing to photoelectric conversion are not necessarily limited to visible ray wavelengths. Furthermore, since the solar cell module of the present invention has the wavelength-converting encapsulant layer, the polymer fluorescent dye compound does not precipitate even in a long-term storage test of the module, so that the polymer fluorescent dye compound can be restrained from being shifted to the encapsulant layer 40 for the rear surface, or to some other member. Thus, the solar cell module is a stable and uniform solar cell module.

The above-mentioned solar cell may be, for example, a cadmium-sulfide/cadmium-telluride solar cell, a copper indium gallium biselenide solar cell, an amorphous or microcrystalline silicon solar cell, or a crystal silicon solar cell. More specifically, the solar cell can be applied to a silicon solar cell, using, e.g., an amorphous silicon or polycrystal silicon, a compound semiconductor solar cell using, e.g., GaAs, CIS or CIGS, or an organic solar cell such as an organic thin film solar cell, a dye-sensitized solar cell or quantum dot solar cell. In anyone of these cases or cells, ultraviolet ray wavelengths do not easily contribute to photoelectric conversion according to an ordinary use of the cell. The solar cell is preferably a crystal silicon solar cell.

In the production of the solar cell module, the above-mentioned encapsulant layer for a solar cell may be transferred onto the solar cell or the like, or may be applied and formed directly onto the solar cell. The encapsulant layer for a solar cell and any other layer may be simultaneously formed.

The solar cell module of the present invention is preferably configured in such a manner that rays radiated into the module passes through the wavelength-converting encapsulant layer before the rays reach the solar cell. The configuration makes it possible to convert efficiently a broader spectrum of solar energy into electricity, with a higher certainty, to heighten the module in photoelectric conversion efficiency.

The above-mentioned surface protective layer may be a known layer usable as a surface protective layer for a solar cell. The surface protective layer may be, for example, a front sheet, or a glass piece. As the glass piece, various glass pieces may be fittingly used, examples thereof including a white glass plate, or a glass piece with or without embossment.

### EXAMPLES

Hereinafter, a description will be made about working examples thereof that specifically demonstrate the structure and the advantageous effects of the present invention, and others.

### Example 1

AIBN (azobisisobutyronitrile) (7.4 mg) and tetrahydrofuran (2 mL) were used to stir a methacrylate compound (0.50 g) shown as a compound (1) at 80° C. under the atmosphere of nitrogen for 3 hours to yield a polymethacrylate compound (yield: 0.45 g) shown as a compound (2). The number-average molecular weight of the resultant compound (2) was 10500, and the weight-average molecular weight thereof was 17500.

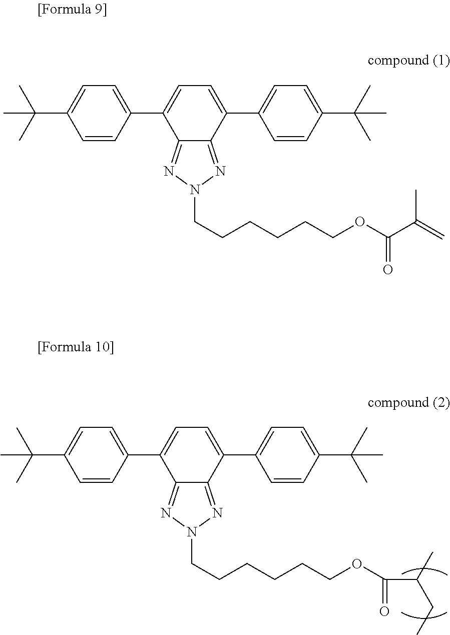

### Example 2

Toluene (4 mL) was used to stir the methacrylate compound (0.50 g) shown as the compound (1), butyl acrylate (0.50 g), and AIBN (azobisisobutyronitrile) (15 mg) at 80° C. under the atmosphere of nitrogen for 3 hours to yield a polymethacrylate compound (yield: 0.91 g) shown as a compound (3), which is a copolymer. The number-average molecular weight of the resultant compound (3) was 10200, and the weight-average molecular weight thereof was 16000.

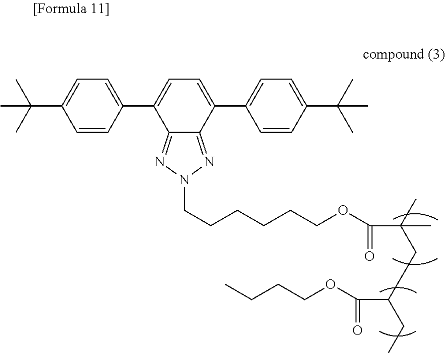

### Example 3

A hydroxyl-group-containing compound (0.50 g) shown as a compound (4) and a poly(ethylene-methyl acrylate) (EMMA resin, manufactured by Sumitomo Chemical Co., Ltd.; 10 g) were stirred at 100° C. in toluene (50 mL) under the atmosphere of nitrogen for 3 hours, using titanium tetraethoxide (30 mg) to yield a poly(ethylene-acrylate) compound (yield: 8.5 g) shown as a compound (5), which is a copolymer. The number-average molecular weight of the resultant compound (5) was 49000, and the weight-average molecular weight thereof was 124000.

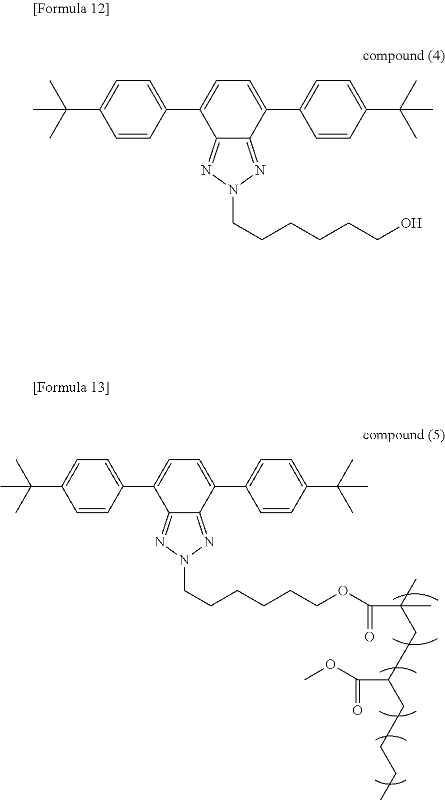

### Example 4

A poly(ethylene-vinyl acetate) (KA30, manufactured by Sumitomo Chemical Co., Ltd.; 10 g) was dissolved into toluene (100 g), and thereto was added sodium methoxide (0.54 g). The resultant was stirred at room temperature for 3 hours to yield a polymer solution in which acetyl groups of the poly(ethylene-vinyl acetate) were partially hydrolyzed. Subsequently, to this polymer solution were added a hydrochloride salt (9.6 g) of 1-(3-dimethylaminopropyl)-3-ethylcarbodiimide, a carboxylic-acid-containing compound (0.1 g) shown as a compound (6), and dimethylaminopyridine (catalytic amount). The resultant was stirred at room temperature for 6 hours. Thereafter, thereto was added acetic acid (0.5 g), and the resultant was stirred at room temperature (25° C.) for 6 hours to yield a poly(ethylene-vinyl acrylate-acyloxy) compound (yield: 8.3 g) shown as a compound (7), which is a copolymer. The number-average molecular weight of the resultant compound (7) was 49900, and the weight-average molecular weight thereof was 125000.

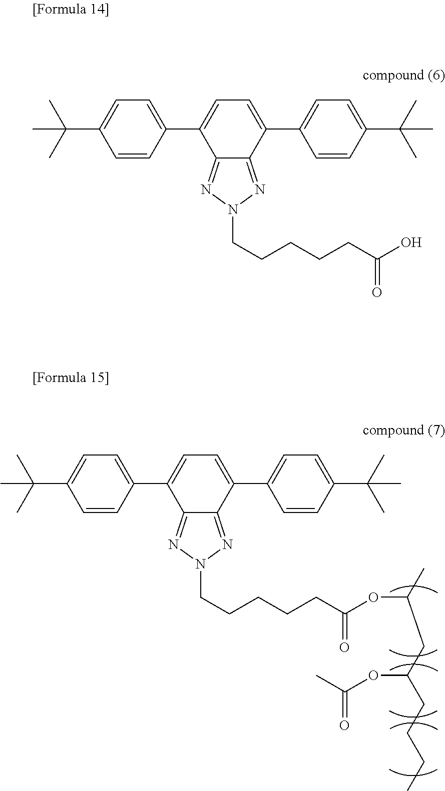

### Example 5

The same manner as in Example 4 was performed except that the use amount of the carboxylic-acid-containing compound shown as the compound (6) was changed into 0.02 g to yield a compound (7′) (yield: 8.1 g), which is a copolymer having a structure similar to that of the compound (7). The number-average molecular weight of the resultant compound (7′) was 51900, and the weight-average molecular weight thereof was 129000.

### Example 6

Isobutyl bromide (0.50 g), potassium carbonate (0.55 g) and dimethylformamide (5 mL) were used to stir a chlorine-radical-containing compound (0.50 g) shown as a compound (8) and a phenolic novolak (MEH-7851SS, manufactured by Meiwa Plastic Industries, Ltd.; 0.42 g) at 130° C. under the atmosphere of nitrogen for 3 hours to yield a compound (yield: 0.65 g) shown as a compound (9), in which hydroxyl groups of the phenolic novolak were etherized. The number-average molecular weight of the resultant compound (9) was 3200, and the weight-average molecular weight thereof was 7700.

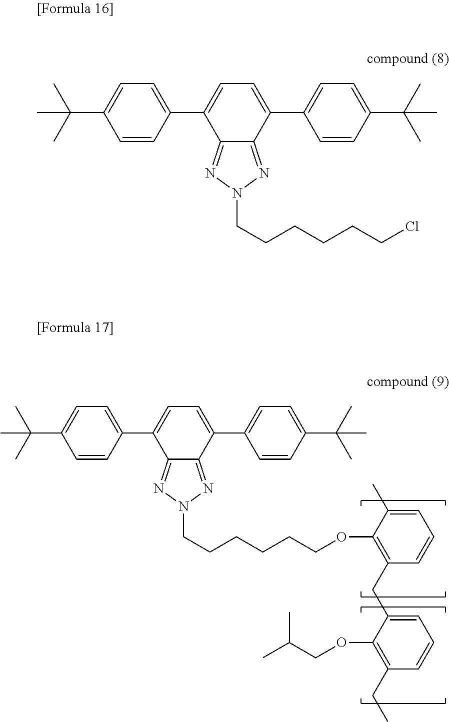

### Example 7

A poly(ethylene-vinyl acetate) (KA30, manufactured by Sumitomo Chemical Co., Ltd.; 70 g) and the methacrylate-group-introduced compound (0.50 g) shown as the compound (1) were kneaded and vacuum-pressed to yield a film (thickness: 100 μm) in which the crosslinkable-group-containing dye compound was dispersed in a matrix of EVA. An electron beam radiating device (EBC300-60, manufactured by NHV Corp.) was used to radiate an electron beam to the resultant film (under the atmosphere of nitrogen at an accelerating voltage of 250 keV and a radiation value of 90 kGy) to yield a copolymer in which the fluorescent dye compound was graft-polymerized to the EVA matrix.

### Example 8

A copolymer in which the fluorescent dye compound was graft-polymerized to the EVA matrix was yielded in the same way as in Example 7 except that a hexene-group-containing compound (0.50 g) shown as a compound (10) was used instead of the methacrylate-group-containing compound (0.50 g) shown as the compound (1).

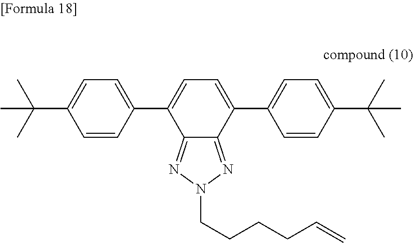 [SMILES: C=CCCCCn1nc2c(-c3ccc(C(C)(C)C)cc3)ccc(-c3ccc(C(C)(C)C)cc3)c2n1]

### Comparative Example 1

Dichlorobistriphenylphosphine palladium (5 mg), potassium carbonate (1.04 g), water (2 mL) and toluene (4 mL) were used to stir a dibromo compound (0.50 g) shown as a compound (11) and 4-tert-butyphenylboronic acid (0.59 g) at 110° C. under the atmosphere of nitrogen for 2 hours to yield an aromatic low-molecular-weight compound (yield: 0.57 g) shown as a compound (12). The molecular weight of the resultant compound (12) is calculable out from the chemical formula thereof. It is evident that the molecular weight is 439.64.

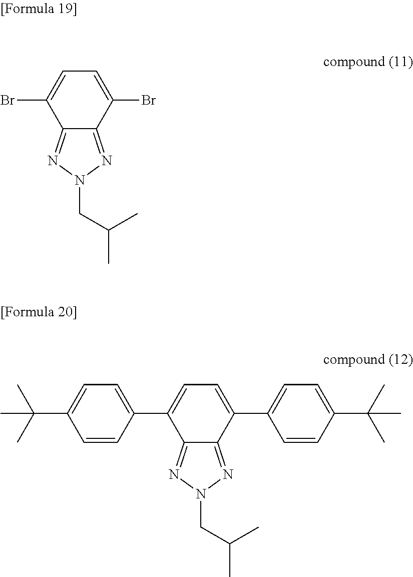 [SMILES: CC(C)Cn1nc2c(Br)ccc(Br)c2n1 ; CC(C)Cn1nc2c(-c3ccc(C(C)(C)C)cc3)ccc(-c3ccc(C(C)(C)C)cc3)c2n1]

### Comparative Example 2

Palladium carbon (Pd: 10%; approximately-55%-water wetted product) (30 mg), potassium carbonate (1.03 g), water (2 mL) and isopropyl alcohol (2 mL) were used to stir the dibromo compound (0.5 g) shown as the compound (11) and 4,4′-biphenyldiboronic acid (0.38 g) at 85° C. under the atmosphere of air for 4 hours to yield an aromatic compound (yield: 0.05 g) shown as a compound (12). The number-average molecular weight of the resultant compound (13) was 3500, and the weight-average molecular weight thereof was 7500.

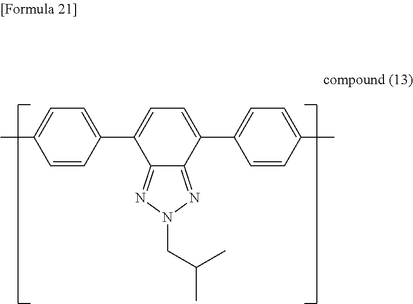

### Comparative Example 3

2-Hydroxy-4-n-octyloxybenzophenone was used, which is an ultraviolet absorbent.

### (Measurement of Molecular Weight)

A GPC instrument (HLC-8220 GPC, manufactured by Tosoh Corp.) was used to measure the number-average molecular weight and the weight-average molecular weight of each of the polymers. Conditions for the measurement were as follows:
Sample concentration: 0.001% by weight (THF solution),
Sample injected volume: 10 μL,
Eluent: chloroform,
Flow rate: 0.3 mL/min,
Measurement temperature: 40° C.,
Columns: TSKgel, Super HZM-H/HZ2000/HZ1000, and
Detector: Differential refractor (RI).

Each of the molecular weights was gained as a value in terms of styrene.

### (Measurement of Maximum Absorption Wavelength, and Fluorescence Emission Wavelength)

Measurements were made about the maximum absorption wavelength and the fluorescence emission wavelength of the fluorescence emission compound used in each of the working examples and the comparative examples. The measurement of the maximum absorption wavelength was made, using an ultraviolet and visible spectrophotometer (V-560, manufactured by JASCO Corp.). The wavelength at which the maximum value was shown in the Abs measurement of the compound was measured.

The measurement of the fluorescence emission wavelength was made, using an instrument F-4500 manufactured by Hitachi High-Technologies Corp. The wavelength at which the maximum emission intensity was shown in the (excitation-emission) three-dimension measurement of the compound was measured.

### (Production of Each Encapsulant Resin Composition)

The following were weighed out: 100 parts by mass of a poly(ethylene-vinyl acetate) (EVA) (KA-30, manufactured by Sumitomo Chemical Co., Ltd.) as a transparent dispersion-medium resin; and the compound of each of the working examples and the comparative examples, the part(s) by weight of which was/were a value shown in Table. A Labo Plastomill (10C100, manufactured by Toyo Seiki Kogyo Co., Ltd.) was used to knead these components at 80° C. to yield a encapsulant resin composition. The compound of Example 5 was used as it was without using the poly(ethylene-vinyl acetate).

### (Production of Each Encapsulant Sheet)

Each of the encapsulant resin compositions yielded as described above was sandwiched between release sheets. A vacuum hot-press machine (VS20-3430, manufactured by Mikado Technos Co., Ltd.) was used to press the workpiece at 100° C. to produce a encapsulant sheet of about 400 μm thickness.

### (Measurement of Efficiency of Each Solar Cell Module)

Each of the encapsulant sheets obtained as described above was cut into a size of 20×20 cm. The following were then put onto each other: a reinforced glass piece (SOLITE, manufactured by Asahi Glass Co., Ltd.) as a protective glass piece; the encapsulant sheet; a solar cell (of a crystal silicon type, Q6LTT3-G2-200/1700-A, manufactured by Hanwha Q CELLS Co., Ltd.); a encapsulant sheet (400-μm-thick EVA sheet) for a rear surface; and a PET film as a back sheet. A vacuum laminator (LM-50×50-S, manufactured by NPC Inc.) was used to laminate these members onto each other at 140° C. in a vacuum state for 5 minutes and a pressured state for 10 minutes to produce a solar cell module.

### (Measurement of Jsc of Each of Solar Cell Modules)

A spectral sensitivity measuring instrument (CEP-25RR, manufactured by JASCO Corp.) was used to measure the spectral sensitivity of each of the solar cell modules yielded as described above. The Jsc value thereof was obtained which was calculated out from the spectral sensitivity measurement. The Jsc value of any sample is the short circuit current density thereof that is calculated out by an arithmetic operation of the following two: a spectral sensitivity spectrum obtained by measuring the sample through a spectral sensitivity measuring instrument; and sunlight as a reference.

According to the measurement of the Jsc value of the solar cell module produced using the encapsulant sheet of each of Example 1 and Comparative Example 3, the Jsc value of the solar cell module of Example 1 was larger than that of the solar cell module of Comparative Example 13 by 1.5%. Thus, the module of Example 1 was improved in photoelectric conversion efficiency.

### (Verification of Fixation Degree of Each of Dyes)

An EVA sheet was produced, using the fluorescence emission compound yielded in each of the working examples and the comparative examples. The produced EVA sheet was immersed in a solvent to be impregnated with the solvent. A spectrophotometer was used to measure the respective absorbances of the sheet before and after the elution-out test. A comparison was then made therebetween.

Each of the resultant encapsulant sheets, the weight of the sheet being 300 mg, was allowed to stand still in 50 mL of isopropyl alcohol at 40° C. for 4 hours, and then an evaluation was made as to whether or not the dye was eluted out. Thereafter, the resultant encapsulant sheet was dried, and then the absorbance of the encapsulant sheet was measured at the maximum absorption wavelength of this sheet. About each of the sheets, a comparison was made between the respective absorbances, at the maximum absorption wavelength, before and after the elution experiment to calculate and evaluate the proportion of the dye fixed to the resin. As the fixation degree of the dye, a value calculated out in accordance with the following equation was used:

Fixation degree (%)={(absorbance after the elution test)/(absorbance before the elution test)}×100

The resultant results are shown in Table 1 described below.

TABLE 1

| | | | Blend | |
|---|---|---|---|---|
| | Maximum | Maximum | proportion (% | Fixation |
| | absorption | emission | by weight) in | degree |
| | wavelength | wavelength | composition | (%) |
| Example 1 | 345 nm | 425 nm | 0.2 | 85 |
| Example 2 | 345 nm | 425 nm | 0.4 | 82 |
| Example 3 | 345 nm | 425 nm | 4 | 87 |
| Example 4 | 345 nm | 425 nm | 20 | 87 |
| Example 5 | 345 nm | 425 nm | 100 | 70 |
| Example 6 | 345 nm | 425 nm | 0.5 | 70 |
| Example 7 | 345 nm | 425 nm | 100 | 90 |
| Example 8 | 345 nm | 425 nm | 100 | 88 |
| Comparative | 345 nm | 425 nm | 0.2 | 9 |
| Example 1 | | | | |
| Comparative | 360 nm | 435 nm | 0.2 | 71 |
| Example 2 | | | | |
| Comparative | 330 nm | Light emission | 0.2 | 8 |
| Example 3 | | not observed | | |

As described above, in each of the resultant sheets, its polymeric wavelength-converting dye compound is taken into its polymeric matrix in such a manner that molecules thereof are entangled with the matrix, or the dye compound itself is a matrix material. Accordingly, even when the sheet is immersed into the solvent to be impregnated with the solvent, the dye compound is not easily eluted out. Thus, it has been understood that the compound of the present application, in which a chromophore having a specific benzotriazole moiety is non-covalently linked to a polymeric structure, is excellent in the property of not being eluted out while the chromophore maintains absorbing/light-emitting properties.

### DESCRIPTION OF REFERENCE SIGNS

1: Solar cell module
10: Surface protective layer
20: Wavelength-converting encapsulant layer
30: Solar cell
40: Backside encapsulant layer
50: Back sheet

1. A polymer fluorescent dye compound, represented by the following general formula (I): 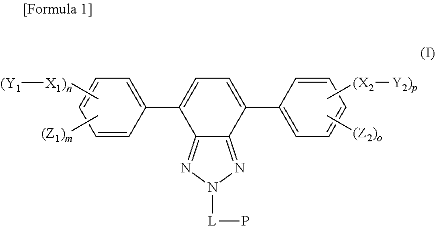
wherein X₁(s) and X₂(s) each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;
Y₁(s) and Y₂(s) each independently represent an optionally-substituted alkyl group having 1 to 18 carbon atoms (provided that one or two out of any nonadjacent two of the carbon atoms in the alkyl group may (each) be substituted with an oxygen atom);
P represents a polymeric structural moiety;
L represents a linker structural moiety through which a benzotriazole ring of the compound and the polymeric structural moiety are bonded to each other by a covalent bond;
Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and
m, n, o and p each independently represent an integer of 0 to 4 (provided that m+n is 4 or less, and o+p is 4 or less), and when m, n, o or p is 2 or more, the substituents concerned may be the same as or different from each other.

2. The polymer fluorescent dye compound according to claim 1, wherein the symbol L is combined neither with the benzotriazole ring nor with the polymeric structural moiety for the formation of any conjugated bond.

3. The polymer fluorescent dye compound according to claim 1, represented by the following general formula (II): 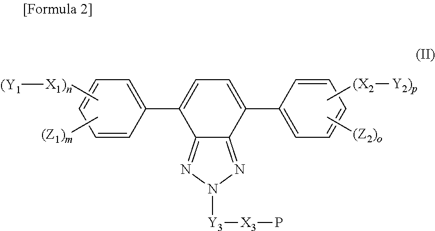
wherein X₁(s), X₂(s) and X₃ each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;
Y₁(s), Y₂(s) and Y₃ each independently represent an optionally-substituted alkyl group having 1 to 18 carbon atoms (provided that one or two out of any nonadjacent two of the carbon atoms in the alkyl group may (each) be substituted with an oxygen atom);
P represents a polymeric structural moiety;
Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, a —COOR¹ group, a —NHCOR² group, or a hydroxyl group wherein R¹ and R² each represent an alkyl group having 1 to 18 carbon atoms or a phenyl group; and
m, n, o and p each independently represent an integer of 0 to 4 (provided that m+n is 4 or less, and o+p is 4 or less), and when m, n, o or p is 2 or more, the substituents concerned may be the same as or different from each other.

4. The polymer fluorescent dye compound according to claim 1, wherein the symbol P is polyethylene terephthalate, poly(meth)acrylate, polyvinyl acetate, polyethylene tetrafluoroethylene, polyimide, amorphous polycarbonate, siloxane sol-gel, polyurethane, polystyrene, polyethersulfone, polyacrylate, epoxy resin, polyethylene, polypropylene, poly(ethylene-vinyl acetate) or silicone resin.

5. The polymer fluorescent dye compound according claim 1, which has a maximum absorption wavelength in a range from 300 to 410 nm.

6. The polymer fluorescent dye compound according to claim 1, which has a maximum fluorescence emission wavelength in a range from 410 to 560 nm.

7. A wavelength-converting encapsulant composition, comprising the polymer fluorescent dye compound according to claim 1 in a proportion of 0.05 to 100% by weight.

8. A wavelength-converting encapsulant composition, comprising an optically transparent resin matrix, and the polymer fluorescent dye compound according to claim 1.

9. The wavelength-converting encapsulant composition according to claim 8, wherein the matrix resin comprises, as a main component thereof, poly(ethylene-vinyl acetate).

10. A wavelength-converting encapsulant layer, which is formed using the wavelength-converting encapsulant composition according to claim 7.

11. A solar cell module, comprising a wavelength-converting encapsulant layer formed using the wavelength-converting encapsulant composition according to claim 7.

12. The solar cell module according to claim 11, which is configured to cause a light ray radiated into the module to pass through the wavelength-converting encapsulant layer before the light ray reaches a solar cell of the module.

13. The solar cell module according to claim 11, wherein the solar cell is a crystal silicon solar cell.
